(19) United States
(12) Patent Application Publication
(10) Pub. No.: US 2026/0181267 A1
(43) Pub. Date: Jun. 25, 2026

(54) METHOD AND DEVICE FOR ELECTRICALLY CONTACTING OF ELECTRONIC COMPONENTS

(71) Applicant: ams-OSRAM International GmbH, Regensburg (DE)

(72) Inventors: Christoph KOLLER, Hemau (DE); Michael KOLLER, Hemau (DE); Stefan MERL, Schwandorf (DE)

(21) Appl. No.: 19/113,108

(22) PCT Filed: Sep. 18, 2023
(86) PCT No.: PCT/EP2023/075699

§ 371 Date: Mar. 19, 2025

(30) Foreign Application Priority Data
Sep. 21, 2022 (DE) 10 2022 124 300.1

(51) Int. Cl. H04N 23/90; H01R 13/17; H05K 1/02; H05K 1/189; H10W 72/90; H10W 90/00

(52) U.S. Cl. CPC H04N 23/90; H01R 13/17; H05K 1/028; H05K 1/189; H10W 72/90; H10W 90/734

(57) ABSTRACT

A method of electrically contacting at least one electronic includes providing a flexible element including a first main surface on which a first conductor trace and a second conductor are arranged, providing a first wire and a second wire, arranging the flexible element with respect to the at least one component with the first main surface facing the at least one component, bending and pressing the flexible element onto the at least one component such that a first contact element of the at least one component contacts the first and the second conductor trace, contacting a second contact element of the at least one component with the first and second wires, applying a current to the at least one first conductor trace and the first wire, and measuring a voltage drop across the at least one component via the at least one second conductor trace and the second wire.

The present application claims the priority of German patent application No. 10 2022 124 300.1 dated Sep. 21, 2022, the disclosure of which is hereby incorporated by reference into the present application.

The present invention relates to a method and a device for electrically contacting components which are integrated, for example, in a semiconductor wafer.

With conventional methods, semiconductor wafers, which contain electronic or optoelectronic components in particular, can only be measured with a comparatively high expenditure of time.

DE102019107138 shows a method in which the components integrated in a semiconductor wafer can be electrically contacted with reduced time expenditure. The conductor traces arranged on a bendable printed circuit board (flexboard) are designed and arranged in such a way that one conductor trace is provided on the flexboard for each row of components on the wafer. The voltage drop across the components is measured via the same path that is used to apply a current to the components

However, the inventors have recognized that an undefined contact transition resistance between the conductor trace and the contact pad of a component to be measured can cause a voltage drop across the components, which is measured via the same path via which a current is applied to the components, to be greatly distorted. This is due to the fact that an undefined and sometimes relatively high contact transition resistance can cause an undefined and undetectable additional voltage to drop across the undefined and sometimes relatively high contact transition resistance with a corresponding current flow (for example due to impurities on or damage to the contact pad), which is difficult or impossible to eliminate afterwards. Contact transition resistance on the back of the wafer, contamination on the conductor traces or damage to the conductor traces cannot be taken into account using known methods either, meaning that reliable and precise voltage measurement across the components is not possible.

A further problem recognized by the inventors is that components with a recessed contact pad or a contact pad arranged in a cavity or offset downwards cannot be contacted using known methods. In particular, the contact pads of such components cannot be contacted with the previously used planar conductor traces on a flexboard, as these conductor traces rest on the highest point (component surface) and do not reach the recess of the contact pads. This means that no electrical contact can be made between the conductor trace and the component contact pad.

In addition, alignment of the component and measuring equipment has so far generally been carried out manually using a camera and manually operated adjustment screws for an X and Y position, as well as a rotational position around the Z axis of a holding device for the components (e.g. a wafer table). On the one hand, such a procedure is very time-consuming and on the other hand, manual correction of the alignment must be carried out again after each change of a component or wafer comprising the components or the measuring equipment.

The present invention is therefore based on the task of providing a method and a device by means of which at least one of the aforementioned problems can be solved.

A task of the invention is solved by a method having the features of claim 1, and by a method having the features of claim 11. A task of the invention is further solved by a device having the features of independent claim 13, and by a device having the features of claim 16. Preferred embodiments and further embodiments of the invention are given in the dependent claims.

A method according to one embodiment is used for electrically contacting at least one electrical or optoelectronic component or several electrical or optoelectronic components which are integrated, for example, in a semiconductor wafer or mold wafer, or are arranged on a ceramic substrate or a circuit board.

In the case of several components, these are not separated during electrical contacting, but are still in the wafer com-pound or are arranged on a carrier in a corresponding grid with predefined distances from each other. The semiconductor wafer can be understood as the wafer on which the components are formed. The components are arranged in the semiconductor wafer in a matrix of rows and columns, for example. The semiconductor wafer contains semiconductor material, but need not consist exclusively of semiconductor material, but may also comprise metals and/or insulators, for example. After the process described in the present application has been carried out, the components can be separated to form semiconductor chips, for example by means of sawing.

The method provides for a flexible element comprising a first main surface on which at least one first conductor trace and at least one second conductor trace electrically insulated from the at least one first conductor trace are arranged.

The flexible element is arranged in relation to the at least one component in such a way that the first main surface of the flexible element, on which the conductive tracks are located, faces the at least one component. For example, the flexible element is arranged above the at least one component.

Furthermore, the flexible element is bent and pressed onto the at least one component in such a way that a first contact element of the at least one component comes into contact with the at least one first and the at least one second conductor trace. The first contact element can be electrically contacted by the conductor traces, which makes it possible to apply an electrical signal to the at least one component or to measure an electrical parameter via the at least one component.

In order to apply the electrical signal or to be able to measure an electrical parameter via the at least one component, a first wire and a second wire electrically insulated from the first wire are also provided, which are each connected to a second contact element of the at least one component and thus contact the latter.

A defined, in particular constant current or a constant voltage is applied to the at least one first conductor trace and the first wire in order to operate the at least one component for testing purposes. At the same time, the reaction of the applied constant current or the constant voltage, for example the voltage drop across the at least one component, is measured via the at least one second conductor trace and the second wire in order to be able to make a statement about the functionality of the at least one component on the basis of the measured value.

Such a measurement makes it possible to determine a voltage drop across the at least one component during its operation largely independently of a contact resistance between the conductors and lines and the contact elements and is based on the principle of a three-point method or three-wire measurement or on the principle of a four-point method or four-wire measurement. A controlled and defined current flows via the at least one first conductor trace and the first wire, while the potential differ-ence or the electrical voltage that drops across the at least one component during its operation is measured via the at least one second conductor trace and the second wire. In particular, the “current-free” voltage measurement via the at least one second conductor trace and the second wire is independent of a contact resistance. In the case of a three-wire measurement, the first and second wires can be brought together at a point before they contact the second contact element, resulting in a three-wire measurement as opposed to a four-wire measurement.

Electrical signals can be measured accordingly via the conductor paths and lines, in particular in response to the electrical signals applied to the at least one component. This allows the function of the at least one component to be checked. For example, a current-voltage characteristic of the at least one component can be recorded. Alternatively, only one or more points on the current-voltage characteristic curve can be recorded.

The flexible element can comprise, for example, a printed circuit board (PCB), printed circuit board or printed circuit board, which comprises a suitable flexible element. A printed circuit board comprises a body made of electrically insulating material with conductive tracks adhering to it. Fiber-reinforced plastic can be used as the electrically insulating material. For example, glass fibers can be embedded in a polyimide or an epoxy or silicone resin. The desired flexibility of the printed circuit board can be achieved in particular by a correspondingly low thickness of the printed circuit board.

However, the flexible element can also be formed by a thin film, such as a thin plastic film, for example a polyimide or polyethylene or polyethylene terephthalate film, on which the conductor traces are arranged, for example printed.

The conductive tracks can be etched from a thin layer or printed onto the flexible element. For example, the conductor traces can comprise copper as the material for the conductor trace, e.g. rolled copper (high flexibility) or electrolytic copper (more brittle).

The conductor traces can be essentially straight or linear and aligned parallel to each other. The respective width of the conductor traces can be in the range of 8 to 200 μm. Such a width makes it possible to contact even small contact elements or bond pads of the at least one component, which typically comprise widths in the range of 60 to 140 μm.

The flexible element can be bent with the aid of a tool. The tool, for example a doctor blade, which comprises in particular a blade geometry, can be pressed onto a second main surface of the flexible element opposite the first main surface in such a way that the flexible element is bent in the desired manner. The flexible element can be attached at two opposite ends to a suitable holder. The tool makes it possible in a simple manner to bend the flexible element in such a way that the conductor traces arranged on the first main surface of the plate touch the first contact element of the at least one component.

According to one embodiment, the first contact element is arranged on a top surface of the at least one component and the second contact element is arranged on a lower side of the at least one component opposite the top surface. The first and second contact elements can, for example, be an anode and cath-ode connection via which the at least one component can be connected in the vertical direction. In this case, the first and second wires can be formed by electrical connections on the bottom surface of the at least one component which contact the second contact element.

According to an alternative embodiment, the at least one component has a so-called flip-chip configuration, i.e. all electrical contact elements are arranged on the top surface of the at least one component facing the plate. In this case, the first wire can be formed by at least one third conductor trace on the first main surface, which is electrically insulated from the at least one first and at least one second conductor trace, and the second wire can be formed by at least one fourth conductor trace on the first main surface, which is electrically insulated from the at least one first, at least one second and at least one third conductor trace. Accordingly, in addition to the at least one first and the at least one second conductor trace, at least one third and at least one fourth conductor trace is arranged on the first main surface, wherein the at least one third and the at least one fourth conductor trace also contact the second contact element of the at least one component by bending and pressing the flexible element onto the at least one component.

In addition to the first and second contact elements, the at least one component can comprise further contact elements, for example signal inputs and outputs or data inputs and outputs, which can also be contacted by means of further conductor traces on the first main surface and to which a signal can be applied. In addition, further measurements can be made via the at least one component using the further contact elements and conductor traces, the results of which can contribute to a statement about the functionality of the at least one component.

The at least one electronic component can be formed in particular by an optoelectronic component that is configured to emit light when a corresponding signal is applied to it. For example, the at least one component can be designed as a light emitting diode (LED), an organic light emitting diode (OLED) or a laser diode (LD).

The light emitted by the at least one optoelectronic component can, for example, be light in the visible range, ultraviolet (UV) light and/or infrared (IR) light.

By applying electrical signals, in particular a current, to the at least one optoelectronic component, it can be excited to generate light. To check the function of the at least one optoelectronic component, the light emitted by the at least one component can be measured using a sensor in addition to the voltage measurement. For example, the sensor can record the light emitted by the component. The sensor can be a scanner or a camera, for example.

The at least one electronic component can also be formed by a sensor, for example a photodiode, or an integrated circuit whose functionality is to be checked.

According to at least one embodiment, the method is used to simultaneously make electrical contact with a plurality of components arranged in series by bending and pressing the flexible element onto the plurality of components arranged in series

In particular, by bending and pressing the flexible element, several components arranged in a row are contacted along a line by the flexible element or the conductor traces located on it. In the case of a semiconductor wafer comprising components arranged in rows and columns, only the contact elements of those components arranged in the same row or row of the semiconductor wafer are brought into contact with the conductor traces at the same time. By bending and pressing the flexible element, in particular the first contact elements of the components arranged in rows come into contact with a first and a second conductor trace in each case.

The multiple first and second conductor traces on the main surface of the flexible element can each be isolated from one another and the current injection or voltage measurement can be carried out separately via each component via the first and second conductor trace connected to the first contact element. However, the first and/or second conductor traces can also comprise a common connection area, so that a current can be connected to the first conductor traces and/or a voltage measurement can be connected to the second conductor traces.

In order to successively contact all or a specific part of the components of the semiconductor wafer, the tool can be moved along the flexible element. By moving the tool along the flexible element, in particular in such a way that contact elements of components arranged in columns come into contact with the conductor traces one after the other, the components of different rows of the semiconductor wafer can be tested one after the other. In particular, the tool moves in a direction parallel to the conductor traces or perpendicular to the component rows of the semiconductor wafer.

Alternatively, it would also be conceivable to design the flexible element to be fixed and to move the semiconductor wafer relative to the flexible element in order to be able to test the components line by line.

Since the components arranged in one row of the semiconductor wafer are contacted simultaneously and all rows of the semiconductor wafer are tested successively one after the other, the components can be checked relatively quickly and with little effort.

Compared to other measurement methods, this reduces the measurement time to a few seconds per semiconductor wafer. Furthermore, the method described here does not cause any needle marks on the components, which are often seen as a problem in the further processing of the components.

The second contact elements of the components can be electrically coupled to each other, especially if they are arranged on the bottom surface of the components. This can be ensured, for example, by the semiconductor wafer itself or by a carrier on which the components are arranged. The coupled second contact elements are then contacted with the first and second wires so that the corresponding test or measurement of the components can be carried out.

Each of the conductor traces or lines can be connected to a corresponding test unit for testing or measuring the components.

For current-less voltage measurement via the at least one second conductor trace and the second wire, the second wire can comprise a pin or spring contact pin, by means of which an electrical contact to the second contact element is established. In particular, the pin or spring contact pin can be integrated into a carrier on which the at least one component is arranged and make contact with the second contact element.

According to at least one embodiment, the at least one first and the at least one second conductor trace each comprise at least one protrusion in the direction away from the first main surface. In particular, the protrusions may comprise a height such that a first contact element of the at least one component, which is set back relative to a top surface of the at least one component, can be contacted by means of the at least one first and the at least one second conductor trace. The protrusions result in correspondingly 3D structured bendable conductor traces by means of which components with a recessed contact element can also be electrically contacted, in that the protrusions on the conductor traces engage in the recess in which the contact elements are arranged and the protrusions come into contact with the contact elements.

The protrusions can be realized on the conductor traces made of copper (Cu) or harder materials such as nickel (Ni) or titanium nitride (TiN) in order to achieve long service lives. It is also possible to combine the materials by growing the Cu protrusions on the conductor traces and then coating them with a hard Ni or TiN plating. For good electrical contact resistance and also as corrosion protection, the protrusions can also be coated with a gold layer.

Not least in the case of protrusions on the conductive tracks, but also for all other embodiments of the present invention, it is necessary that the flexible element is aligned with the at least one component with sufficient precision to ensure that the at least one first conductive track and the at least one second conductive track come into contact with the first contact element of the at least one component.

Therefore, a method is also proposed, in particular a method which can be combined with the already described and the further embodiments of a method of the present application, by means of which the position of at least one electrical component relative to a flexible element can be determined. The flexible element can be configured according to the preceding embodiments and comprises a first main surface on which at least one first conductor trace and at least one second conductor trace electrically insulated from the at least one first conductor trace are arranged. The position of the at least one electrical component relative to the flexible element is determined by means of a camera system. For one or more reference points on the component and the flexible element, the camera system determines an offset from a nominal position of the at least one component relative to the flexible element, and can use this to provide an overall statement about the X and Y position and the rotational position about the Z axis of the at least one component relative to the flexible element.

This information can then be used to align the at least one component with respect to the flexible element in such a way that the at least one first and the at least one second conductor trace and a first contact element of the at least one component are opposite each other.

For this purpose, the camera system can be arranged between the at least one component and the flexible element. In particular, the camera system can comprise two mini-cameras with small external dimensions, which are mounted on a motorized arm and can be placed between the at least one component and the flexible element. One of the cameras can be oriented in the direction of the flexible element and one of the cameras in the direction of the at least one component.

The camera, which is directed towards the flexible element, can be used to record the conductor paths and a contact line between the tool and the flexible element. For this purpose, the flexible element can, for example, be at least partially transparent. The second camera, which is directed towards the at least one component, can detect the position of the at least one component.

However, it is also possible for the camera system to be arranged outside the flexible element and the at least one component, for example above the flexible element. The camera system can, for example, comprise a camera that is used to determine the position of the flexible element and the conductor traces on it in relation to the at least one component. For this purpose, the flexible element can, for example, be at least partially transparent, so that both the conductor traces and the at least one component are visible when looking at the flexible element. In particular, at least partially transparent can also be understood to mean that the flexible element is transparent at least for light in the non-visible UV or infrared spectrum, so that it may be possible to use the camera system to determine the position of the flexible element and the conductor traces located thereon relative to the at least one component using light in such a wavelength range.

An image processing system can then process the information obtained and the at least one component can be aligned with respect to the flexible element. The alignment can be automated using servomotors on, for example, a carrier (wafer table) on which the at least one component is arranged. Alternatively, the alignment can also be automated by servomotors on a holder for the flexible element. Such automated alignment of the components prior to a measurement saves an enormous amount of time and also increases the accuracy of the process. Additionally or alternatively, the tool can also be aligned with the flexible element using one or more servomotors.

A device according to one embodiment is used for electrically contacting at least one electronic component, for example a component in a semiconductor wafer. The device comprises a flexible element comprising a first main surface on which at least one first conductor trace and at least one second conductor trace electrically insulated from the at least one first conductor trace is arranged. Furthermore, the device comprises a first conductor and a second conductor electrically insulated from the first conductor, which can be brought into electrical contact with a second contact element of the at least one component. In addition, the device comprises a current or voltage source, or an analog or digital signal source, which is designed to apply a defined current, a defined voltage or a defined analog or digital signal to the at least one first conductor trace and the first wire. Furthermore, the device comprises a measuring device, in particular a voltage measuring device, which is configured to measure a response to the signal applied to the at least one first conductor trace and the first wire, in particular a voltage drop across the at least one component, via the at least one second conductor trace and the second wire. The flexible element is fixed by means of a holder which is configured to hold the flexible element in relation to the at least one component in such a way that the first main surface of the flexible element comprises in the direction of the at least one component. The flexible element is configured to be bent and pressed onto the at least one component in such a way that a first contact element of the at least one component comes into contact with the at least one first and the at least one second conductor trace.

In particular, the at least one first and the at least one second conductor trace can each comprise at least one protrusion in the direction away from the first main surface, the protrusions having a height such that a first contact element of the at least one component, which is set back relative to a top surface of the at least one component, can be contacted via the protrusions by means of the at least one first and the at least one second conductor trace.

A device according to another embodiment for electrically contacting at least one electronic component comprises a flexible element comprising a first main surface on which at least one first conductor trace is arranged. In addition, the device comprises a first wire which can be brought into electrical contact with a second contact element of the at least one component, a current source which is configured to apply a defined current to the at least one first conductor trace and the first wire, and a holder for the flexible element. The holder is configured to hold the flexible element in relation to the at least one component in such a way that the first main surface of the flexible element comprises the direction of the at least one component. The flexible element is configured to be bent and pressed onto the at least one component in such a way that a first contact element of the at least one component comes into contact with the at least one first conductor trace. And the at least one first conductor trace has, in the direction away from the first main surface, at least one protrusion which comprises a height such that a first contact element of the at least one component, which is set back relative to a top surface of the at least one component, can be contacted by means of the at least one first conductor trace.

Such a device can be particularly suitable for carrying out a two-wire or three-wire measurement via the at least one component, wherein the at least one component comprises a first contact element which is set back relative to a top surface of the at least one component and which is difficult to contact using known methods.

Said devices for electrically contacting the at least one component may also comprise the embodiments of the method described above for electrically contacting the at least one component.

The devices may each comprise a tool configured to press on a second main surface of the flexible member opposite the first main surface to bend the flexible member and press it against the at least one structural member.

Furthermore, the devices can each comprise a camera system which is configured to determine the position of the at least one component relative to the flexible element. The camera system can be configured to be arranged between the at least one component and the flexible element.

A movable table, on which the at least one component is arranged and which is designed to be movable, can also be used to align the at least one component and the flexible element with one another.

In the following, embodiments of the invention are explained in more detail with reference to the accompanying drawings. These show schematically:

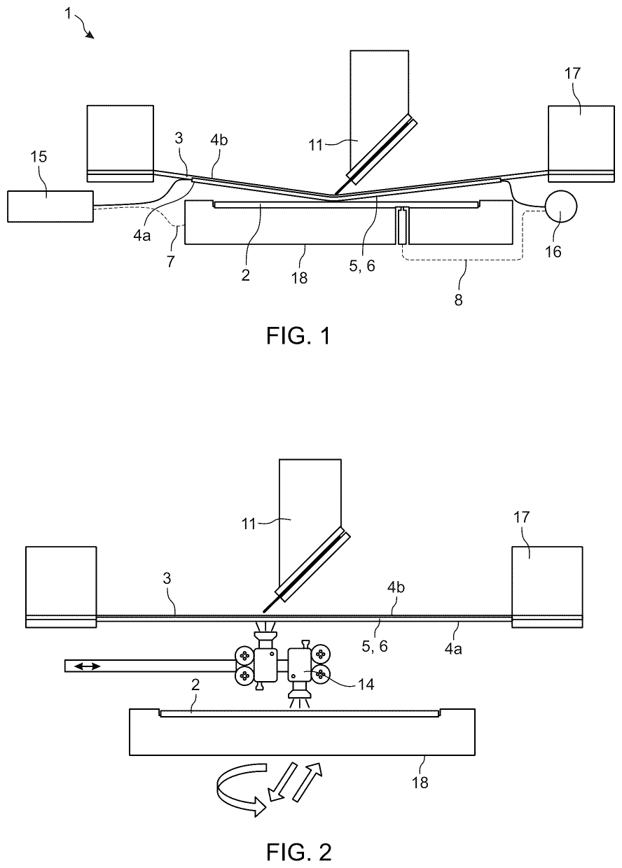

FIG. 1 a device for electrically contacting at least one electronic component according to some aspects of the proposed principle;

FIG. 2 a further embodiment of a device for electrically contacting at least one electronic component according to some aspects of the proposed principle;

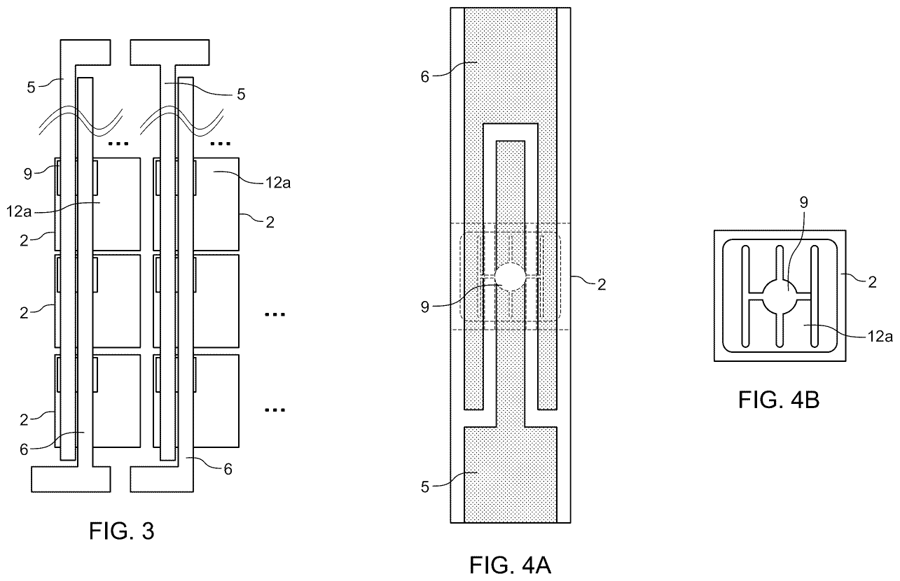

FIG. 3 conductor traces for contacting a contact element of electronic components according to some aspects of the proposed principle;

FIGS. 4A and 4B a further embodiment of a conductor trace design for contacting a contact element of electronic components according to some aspects of the proposed principle as well as an electronic component to be contacted;

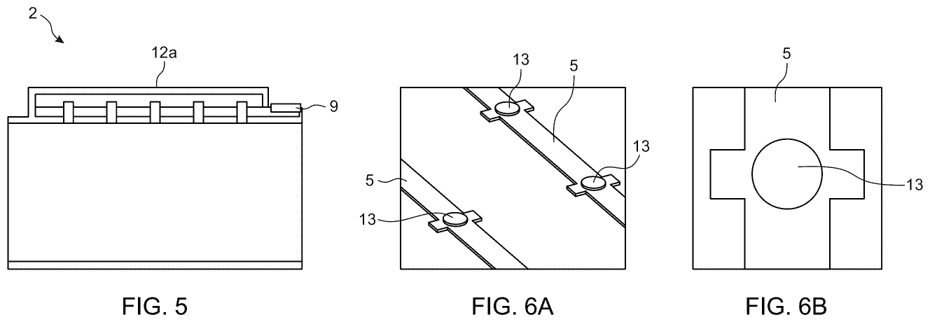

FIG. 5 a side view of an electronic component to be contacted, comprising a contact element set back relative to a top surface of the component; and

FIGS. 6A and 6B a further embodiment of a conductor trace design for contacting a contact element of electronic components according to some aspects of the proposed principle.

In the following detailed description, reference is made to the accompanying drawings, which form a part of this description and in which specific embodiments in which the invention may be practiced are shown for illustrative purposes. Since components of embodiments may be positioned in a number of different ori-entations, the directional terminology is for illustrative purposes and is not limiting in any way. It is understood that other embodiments may be used and structural or logical changes may be made without departing from the scope of protection. It is understood that the features of the various embodiments described herein may be combined with each other, unless specif-ically otherwise indicated. The following detailed description is therefore not to be understood in a restrictive sense. In the figures, identical or similar elements are provided with identical reference signs where this is appropriate.

FIG. 1 shows the schematic structure of a device 1, which is used for the electrical contacting and testing of at least one or more components 2, which are integrated into a semiconductor wafer, for example.

The device 1 comprises a table 18, which holds the at least one component 2 or the plurality of components as part of a semiconductor wafer, and a flexible element 3, for example a flexible printed circuit board or plastic film, with a first main surface 4a and a second main surface 4b opposite the first main surface 4a. The flexible element 3 is fixed in a holder 17 and arranged by means of this in relation to the components 2 in such a way that the first main surface 4a comprises the components 2. A tool 11, for example a squeegee, which comprises in particular a blade geometry, is pressed onto the second main surface 4b, whereby the bending of the originally for example flat flexible element 3 in the direction of the components 2, as shown in FIG. 1, is produced and thus contact is made between the first main surface 4a and not shown first contact elements 9 of the components 2.

On the first main surface 4a of the flexible element, a plurality of first conductor traces 5 and second conductor traces 6 electrically insulated from the first ones are arranged. The force exerted on the flexible element 3 by the tool 11 causes the first and second conductive tracks 5, 6 to make contact with first contact elements 9, not shown in the figure, of a plurality of components 2 arranged in a row. The first and second conductor traces 5, 6 are arranged on the first main surface 4a and are pressed in the direction of the components 2 by means of the tool 11 in such a way that a first and a second conductor trace each contact a first contact element 9 of a plurality of components 2 arranged in a row.

The components 2 are arranged in rows and columns on the table 18, and the flexible element 3 is oriented with respect to the components 2 in such a way that the first and second conductor traces 20 only come into contact with the first contact elements 9 of components 2 arranged in the same row at any one time. In FIG. 1, the row extends perpendicular to the drawing plane.

The device 1 further comprises a first wire 7 and a second wire 8 electrically insulated from the first wire, each of which is in contact with a second contact element 10, not shown, of the components on the bottom surface of the components 2. In particular, the second contact elements of the components 2 can be electrically coupled to one another, for example by a semiconductor wafer in which the components are integrated, or by the table 18 on which the components are arranged. The coupled second contact elements are then contacted with the first and second wires. In the case shown, contact is made between the second wire and the coupled second contact elements via a pin or spring contact pin that extends through the table 18.

A current source 15 is connected to the first conductor traces 5 and the first wire 7, by means of which a current, in particular a constant current, is applied to the contacted components 2. One or more voltage measuring devices 16 are connected to the second conductor traces 6 and the second wire 8, by means of which a voltage drop can be measured across the contacted and energized components 2. The information obtained can be used to make a statement about the functionality of the contacted and energized components 2. The separate and in particular cur-rent-less measurement of the voltage drop across the contacted and energized components 2 has the advantage that a possible contact resistance between conductor traces and contact elements or lines and contact elements has no or only very little effect on the measurement. This can improve the significance of the measurement.

FIG. 2 shows a further embodiment of the device 1. The device 1 additionally comprises a camera system 14 for detecting the position of the components 2 relative to the flexible element 3. For one or more reference points on the components and the flexible element 3, the camera system 14 determines an offset occurring relative to a nominal position of the components 2 relative to the flexible element 3, and can provide an overall statement about the X and Y position, as well as the rotational position about the Z axis of the components 2 relative to the flexible element 3.

This information can then be used to align the table 18 on which the components are arranged in relation to the flexible element 3 in such a way that the first and second conductor traces 5, 6 and a first contact element 9 of each component 2 are opposite each other.

In the case shown, the camera system 14 comprises two cameras with small external dimensions, which are mounted on a movable bracket and are inserted between the components 2 and the flexible element 3. One of the cameras is oriented in the direction of the flexible element 3 and one of the cameras is oriented in the direction of the components 2.

The camera, which is directed towards the flexible element, can be used to record the conductor paths and a contact line between the tool and the flexible element. For this purpose, the flexible element can, for example, be at least partially transparent. The second camera, which is directed towards the at least one component, can detect the position of the at least one component. An image processing system can then process the information obtained and the table 18 with the components 2 arranged on it can be aligned with respect to the flexible element 3. The alignment can be automated using servomotors by moving the table in the X and Y directions and by rotating it around the Z axis (shown by the arrows below the table 18).

FIG. 3 shows first and second conductor traces 5, 6 or a conductor trace design on the first main surface 4a of the flexible element 3 for contacting the first contact elements 9 of one or more optoelectronic components 2. As an example, six components arranged in a matrix are shown in the illustration, but the dots to the right and above the components 2 are intended to make it clear that further components can be arranged in the same way in the corresponding direction.

On the first main surface 4a of the flexible element, a plurality of first conductor traces 5 and second conductor traces 6 electrically insulated from the first ones are arranged. The force exerted by the tool 11 on the flexible element 3 causes the first and second conductor traces 5, 6 to come into contact with first contact elements 9, not shown in the figure, of a plurality of components 2 arranged in a row. The first and second conductor traces 5, 6 are arranged on the first main surface 4a and are pressed by the tool 11 in the direction of the components 2 in such a way that a first and a second conductor trace contact a first contact element 9 of a plurality of components 2 arranged in a row.

The components 2 are arranged in rows and columns, and the first and second conductive tracks 5, 6 are arranged on the first main surface 4a of the flexible element 3 and oriented with respect to the components 2 in such a way that a first and second conductive track 5, 6 respectively lie opposite first contact elements 9 of a column of components 2. By pressing on the tool 11, for example a squeegee, which comprises in particular a blade geometry oriented in the direction of the rows of components, the arrangement and orientation of the components relative to one another means that the first and second conductive tracks 5, 6 only come into contact with the first contact elements 9 of components 2 arranged in the same row at any one time.

FIG. 4A shows a further embodiment of a conductor trace design for contacting a first contact element 9 of optoelectronic components 2. The first and second conductor traces 5, 6 are arranged on the first main surface 4a in an interlocking and spaced-apart manner, similar to a zipper arrangement. The second conductor trace comprises two sections, each of which contacts the first contact element 9, between which a first conductor trace 5 is arranged, which contacts the first contact element 9. The arrangement shown results in two contact points for the voltage measurement on the first contact element 9, so that an error rate in the voltage measurement can be reduced if one of the sections of the second conductor trace 6 does not come into contact with the first contact element 9. In addition, a possible positioning inaccuracy between the conductor trace and contact element can be compensated for by the two sections. For this purpose, the components 2 comprise a first contact element 9 as shown in FIG. 4B on their top surface 12a, so that contacting of the first contact element 9 with the conductor trace design shown in FIG. 4A is possible.

FIG. 5 shows an optoelectronic component 2 in which the first contact element 9 is offset downwards relative to a top surface 12a of the optoelectronic component 2. With the method and the conductive tracks shown above, it would not be possible to contact the first contact element 9 with such a configuration of the component 2, as the conductive tracks would rest on the top surface 12a but would not contact the first contact element.

In order to nevertheless be able to contact the first contact elements 9, the conductor traces according to a design as shown in FIGS. 6A and 6B have protrusions 13 which comprise a height such that a first contact element 9 which is set back relative to a top surface 12a of the components 2 can be contacted by means of the conductor traces.

In order to ensure improved alignment of the conductor traces and, in particular, of the protrusions 13 relative to the first contact elements 9, the conductor traces in the case shown comprise lateral bulges, similar to a cross, in the center of which a protrusion 13 is arranged in each case. This bulge or the resulting cross can be used similar to a crosshair to determine the position and subsequent alignment.

### LIST OF REFERENCE SIGNS

1 Device
2 Component
3 Flexible element
4a First main surface
4b Second main surface
5 First conductor trace
6 Second conductor trace
7 First wire
8 Second wire
9 First contact element
10 Second contact element
11 Tool
12a Top surface
12b Bottom surface
13 Protrusion
14 Camera system
15 Current source
16 Voltage measuring device
17 Holder
18 Movable table

1. A method of electrically contacting at least one electronic component comprising the steps of:
providing a flexible element comprising a first main surface on which at least one first conductor trace and at least one second conductor trace electrically insulated from the at least one first conductor trace are arranged;
providing a first wire and a second wire;
arranging the flexible element with respect to the at least one component such that the first main surface faces the at least one component;
bending and pressing the flexible element onto the at least one component in such a way that a first contact element of the at least one component comes into contact with the at least one first and the at least one second conductor trace;
contacting a second contact element of the at least one component with the first and second wires;
applying a defined current to the at least one first conductor trace and the first wire; and
measuring a voltage drop across the at least one component via the at least one second conductor trace and the second wire.

2. The method according to claim 1, wherein the flexible element is bent by means of a tool which is pressed onto a second main surface of the flexible element opposite the first main surface.

3. The method according to claim 1, wherein the first contact element is arranged on an top surface of the at least one component and the second contact element is arranged on bottom surface of the at least one component opposite the top surface.

4. The method according to claim 1, wherein the first and second contact elements are arranged on a top surface of the at least one component, and wherein the first wire is formed by at least one third conductor trace on the first main surface, said third conductor trace being electrically insulated from the at least one first and the at least one second conductor trace, and wherein the second wire is formed by at least one fourth conductor trace on the first main surface, said fourth conductor trace being electrically insulated from the at least one first, the at least one second and the at least one third conductor trace.

5. The method according to claim 1, wherein by means of the method a plurality of components arranged in series are electrically contacted simultaneously by bending and pressing the flexible element onto the plurality of components arranged in series.

6. The method according to claim 5, wherein by bending and pressing the flexible element, the first contact elements of the components arranged in series each come into contact with a first and a second conductor trace.

7. The method according to claim 5, wherein the second contact elements of the components arranged in series are electrically coupled to one another, and the coupled second contact elements are contacted with the first and second wires.

8. The method according to claim 5, wherein the tool is moved along the flexible element such that the first contact elements of components arranged in columns make contact with the conductor traces one after the other.

9. The method according to claim 1, wherein the at least one first and the at least one second conductor trace each comprise at least one protrusion in a direction away from the first main surface.

10. The method according to claim 9, wherein the protrusions comprise a height such that a first contact element of the at least one component, which is set back relative to a top surface of the at least one component, can be contacted by means of the at least one first and the at least one second conductor trace.

11. A method, in particular according to claim 1, comprising the steps of:
detecting, by means of a camera system, the position of at least one electronic component relative to a flexible element comprising a first main surface on which at least one first conductor trace and at least one second conductor trace electrically insulated from the at least one first conductor trace are arranged; and
aligning the at least one component relative to the flexible element in such a way that the at least one first and the at least one second conductor trace and a first contact element of the at least one component are opposite one another.

12. The method according to claim 11, wherein the camera system for detecting the position is arranged between the at least one component and the flexible element.

13. A device for electrically contacting at least one electronic component comprising:
a flexible element comprising a first main surface on which at least one first conductor trace and at least one second conductor trace electrically insulated from the at least one first conductor trace are arranged,
a first wire and a second wire electrically insulated from the first wire, which can be brought into electrical contact with a second contact element of the at least one component,
a current source which is configured to apply a defined current to the at least one first conductor trace and the first wire,
a voltage measuring device which is configured to measure a voltage drop across the at least one second conductor trace and the second wire, and
a holder for the flexible element,
wherein the holder is configured to hold the flexible element in relation to the at least one component in such a way that the first main surface points in the direction of the at least one component, and
wherein the flexible element is configured to be bent and pressed onto the at least one component in such a way that a first contact element of the at least one component comes into contact with the at least one first and the at least one second conductor trace.

14. The device according to claim 13, wherein the at least one first and the at least one second conductor trace each comprise at least one protrusion in a direction away from the first main surface.

15. The device according to any one of claim 13, wherein the protrusions comprise a height such that a first contact element of the at least one component, which is set back relative to a top surface of the at least one component, can be contacted by means of the at least one first and the at least one second conductor trace.

16. A device for electrically contacting at least one electronic component comprising:
a flexible element comprising a first main surface on which at least one first conductor trace is arranged,
a first wire which can be brought into electrical contact with a second contact element of at least one component,
a current source which is configured to apply a defined current to the at least one first conductor trace and the first wire, and
a holder for the flexible element,
wherein the holder is configured to hold the flexible element in relation to the at least one component in such a way that the first main surface points in the direction of the at least one component,
wherein the flexible element is configured to be bent and pressed onto the at least one component in such a way that a first contact element of the at least one component makes contact with the at least one first conductor trace, and
wherein the at least one first conductor trace comprises at least one protrusion in a direction away from the first main surface, which has such a height that a first contact element of the at least one component, which is set back relative to a top surface of the at least one component, can be contacted by means of the at least one first conductor trace.

17. The device according to claim 13, wherein the device comprises a tool configured to press on a second main surface of the flexible member opposite the first main surface to bend the flexible member.

18. The device according to claim 13, further comprising a camera system configured to determine the position of the at least one electronic component relative to the flexible element.

19. The device according to claim 18, wherein the camera system is configured to be arranged between the at least one component and the flexible element.

20. The device according to claim 13, further comprising a movable table on which the at least one component is arranged, and which is movably designed to be able to align the at least one component and the flexible element with respect to each other.
